(19) United States
(12) Patent Application Publication
(10) Pub. No.: US 2025/0203835 A1
(43) Pub. Date: Jun. 19, 2025

(54) KITTING DEVICE EXTRACTION SYSTEM

(71) Applicant: FUJI CORPORATION, Chiryu (JP)

(72) Inventor: Mizuho NOZAWA, Kota-cho (JP)

(73) Assignee: FUJI CORPORATION, Chiryu (JP)

(21) Appl. No.: 18/849,854

(22) PCT Filed: Apr. 26, 2022
(86) PCT No.: PCT/JP2022/018879

§ 371 Date: Sep. 23, 2024

(51) Int. Cl. H05K 13/02; H05K 13/04

(52) U.S. Cl. CPC H05K 13/021; H05K 13/0419

(57) ABSTRACT

A kitting device extraction system includes multiple types of kitting devices and an extraction section. The multiple types of kitting devices are different from each other in setting work of setting a reel, on which a carrier tape for accommodating components is wound, on a feeder. The extraction section extracts a corresponding kitting device capable of performing the setting work based on a state of the reel from the multiple types of kitting devices.

### TECHNICAL FIELD

The present description discloses a technique related to a kitting device extraction system.

### BACKGROUND ART

In an off-line setup device for electronic components described in Patent Literature 1, a feeder is set in a feeder cart according to a production model, or a feeding tape having electronic components is set in the feeder already set in the feeder cart. Further, the off-line setup device for electronic components includes off-line setup data, a reading means, and a replacement error prevention control means. The off-line setup data includes, according to the production model, at least one of feeder information to be set in the feeder cart and electronic component information of the electronic components. The reading means reads correspondence data corresponding to the off-line setup data from a target to be set. The replacement error prevention control means prevents an error in replacement of a target to be set based on the off-line setup data and the correspondence data.

The component mounting system described in Patent Literature 2 has a function of mounting components on a board, and includes a component mounting line, a host computer, an off-line setup device, and a communication network. The component mounting line includes a printing device and multiple component mounters, which are disposed to be linked up to each other in a conveyance direction of the board. The host computer comprehensively controls the component mounting line and the off-line setup device. The off-line setup device performs the setup change work required for switching a model of the board produced in the component mounting line, outside the component mounting line. The communication network communicably connects the component mounting line, the host computer, and the off-line setup device.

### PATENT LITERATURE

Patent Literature 1: JP-A-2011-108909
Patent Literature 2: JP-A-2017-005075

### SUMMARY OF THE INVENTION

### Technical Problem

As a kitting device for setting a reel on a feeder, there are multiple types of kitting devices that perform different setting work for setting a reel on a feeder. Therefore, it is necessary to extract a corresponding kitting device capable of performing the setting work according to a state of the reel.

In view of such circumstances, the present description discloses a kitting device extraction system that extracts a corresponding kitting device capable of performing setting work based on a state of a reel.

### Solution to Problem

The present description discloses a kitting device extraction system including multiple types of kitting devices and an extraction section. The multiple types of kitting devices are different from each other in setting work of setting a reel, on which a carrier tape for accommodating components is wound, on a feeder. The extraction section extracts a corresponding kitting device capable of performing the setting work based on a state of the reel from the multiple types of kitting devices.

### Advantageous Effect of the Invention

With the kitting device extraction system described above, it is possible to extract a corresponding kitting device capable of performing setting work based on a state of a reel.

### BRIEF DESCRIPTION OF DRAWINGS

FIG. 1 is a perspective view illustrating an example of a setup device.

FIG. 2 is a plan view of the setup device in FIG. 1.

FIG. 3 is a perspective view illustrating an example of a feeder provided in a feeder holding section.

FIG. 4 is a plan view illustrating an example of a carrier tape.

FIG. 5 is a cross-sectional view of the carrier tape in FIG. 4.

FIG. 6 is a flowchart illustrating an example of a control procedure by the setup device.

FIG. 7 is a plan view illustrating an example of a feeder unit.

FIG. 8 is a configuration diagram illustrating an example of a kitting device extraction system.

FIG. 9 is a flowchart illustrating an example of a control procedure by the kitting device extraction system.

FIG. 10 is a configuration diagram illustrating an example of a production facility.

FIG. 11 is a schematic view illustrating an example of a tip end portion of the carrier tape.

FIG. 12 is a transparent view of the reel to which the carrier tape is fixed by a first fixing tape, illustrating a first fixing method.

FIG. 13 is a transparent view of the reel to which the carrier tape is fixed by a second fixing tape, illustrating a second fixing method.

FIG. 14 is a transparent view of the reel to which the carrier tape is fixed by a fixing device, illustrating another fixing method.

FIG. 15 is a schematic diagram schematically illustrating an internal mechanism of the setup device.

### DESCRIPTION OF EMBODIMENTS

### 1. Embodiment

### 1-1. Configuration Example of Setup Device 10a

Multiple types of kitting devices 10 are different from each other in setting work of setting reel 70 on which carrier tape 72 for accommodating components 91 is wound on feeder 60. As long as multiple types of kitting devices 10 can set reel 70 on feeder 60, kitting device 10 may take various configurations. For example, multiple types of kitting devices 10 include setup device 10a. Setup device 10a automatically sets reel 70 on feeder 60 so that components 91 can be supplied from feeder 60. As long as setup device 10a can automatically set reel 70 on feeder 60, kitting device 10 may take various configurations.

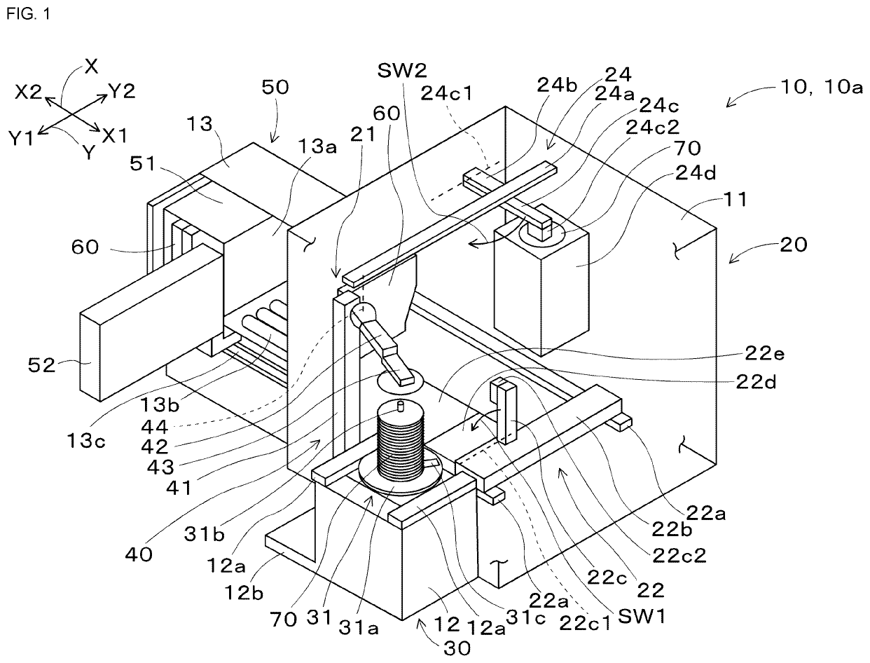

As illustrated in FIGS. 1 to 3, setup device 10a of an embodiment includes reel attachment/detachment section 20, reel supply section 30, reel transfer mechanism 40, and feeder supply section 50. For convenience of description, in the drawings, a facing direction of feeder 60 and reel 70 when reel 70 is attached to and detached from feeder 60 is referred to as a first direction (arrow X direction). In the first direction (arrow X direction), a direction (side) from feeder 60 toward reel 70 is referred to as a first end side (arrow X1 direction) in the first direction, and a direction (side) from reel 70 toward feeder 60 is referred to as a second end side (arrow X2 direction) in the first direction.

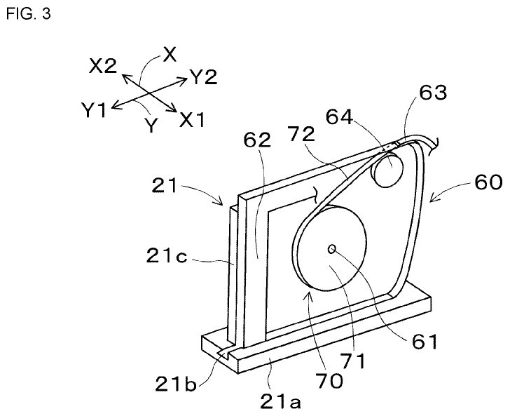

Further, as illustrated in FIG. 3, a sliding direction of feeder 60 in slot 21b, which is a direction orthogonal to the first direction (arrow X direction) in a horizontal plane, is referred to as a second direction (arrow Y direction). In the second direction (arrow Y direction), a sliding direction (side) when feeder 60 is detached is referred to as a first end side (arrow Y1 direction) in the second direction, and a sliding direction (side) when feeder 60 is attached is referred to as a second end side (arrow Y2 direction) in the second direction.

In reel attachment/detachment section 20, various members are assembled inside first housing 11. First housing 11 is a case having a rectangular parallelepiped shape, and a second end side (arrow X2 direction) in the first direction and a first end side (arrow Y1 direction) in the second direction are partially opened. Reel supply section 30 is provided to be coupled to a first end side (arrow Y1 direction) in the second direction of reel attachment/detachment section 20. Reel supply section 30 is formed in box-shaped base 12 smaller than first housing 11. Reel transfer mechanism 40 is provided on plate seat 12b extending from a bottom portion of base 12 to a second end side (arrow X2 direction) in the first direction. Feeder supply section 50 is provided to be coupled to the second end side (arrow X2 direction) in the first direction of reel attachment/detachment section 20. In feeder supply section 50, various members are assembled inside second housing 13 which is smaller than first housing 11 and has storage space 13a in an upper portion.

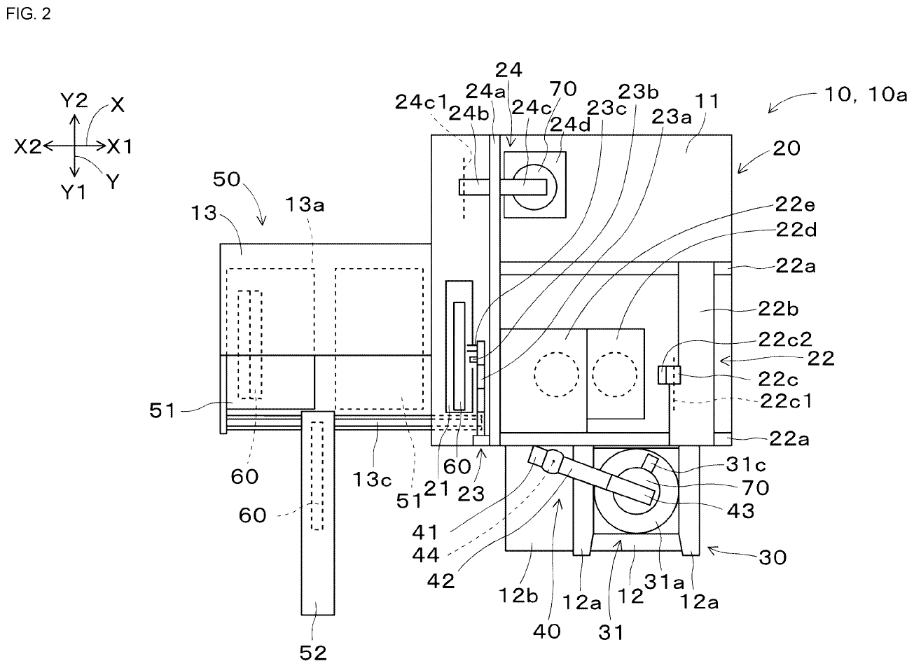

Reel attachment/detachment section 20 includes feeder holding section 21, reel attachment mechanism 22, tape loading mechanism 23, and reel detachment mechanism 24. As illustrated in FIG. 2, feeder holding section 21 is disposed on the second end side (arrow X2 direction) in the first direction and first end side (arrow Y1 direction) in the second direction inside first housing 11. Feeder holding section 21 holds feeder 60 at a work execution position in a vertical posture. As illustrated in FIG. 3, feeder holding section 21 includes bottom plate 21a, slot 21b, and support plate 21c. Slot 21b is formed in a groove shape extending along the second direction (arrow Y direction) in bottom plate 21a. Feeder 60 is inserted from a first end side (arrow Y1 direction) in the second direction of slot 21b toward the second end side (arrow Y2 direction) in the second direction thereof, and is held at the work execution position. Support plate 21c is provided to stand up from bottom plate 21a, and comes into contact with the side surface of feeder 60 at the work execution position on a second end side (arrow X2 direction) in the first direction. Support plate 21c supports a pressing load to the second end side (arrow X2 direction) in the first direction generated when reel 70 is attached to feeder 60.

Feeder 60 is detachably provided on a component mounter. As illustrated in FIG. 3, in feeder 60, reel 70, on which carrier tape 72 is wound, is attached to main body portion 71, and carrier tape 72 is conveyed to supply components 91. An identification code for identifying reel 70 is given to each reel 70. Feeder 60 is formed in a flat box shape. Feeder 60 includes reel holding shaft 61 that protrudes from a side plate at the second end side (arrow X2 direction) in the first direction toward the first end side (arrow X1 direction) in the first direction at a substantially central position as viewed in the first direction (arrow X direction). Reel holding shaft 61 is inserted into a center hole formed at the center of reel 70, and detachably and rotatably holds reel 70.

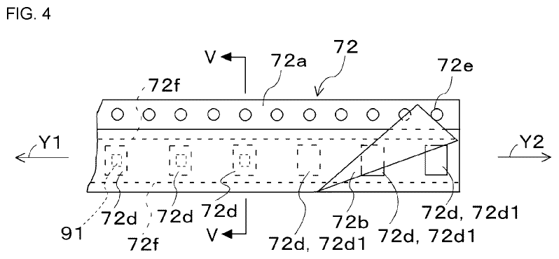

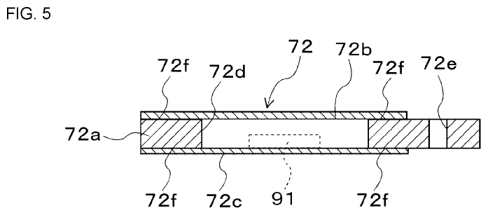

As illustrated in FIGS. 4 and 5, carrier tape 72 includes base tape 72a, cover tape 72b, and bottom tape 72c. Base tape 72a is a base portion of carrier tape 72, and is provided with multiple accommodation sections 72d and multiple feed holes 72e. Component 91 is accommodated in each of multiple accommodation sections 72d. As illustrated in FIG. 4, a predetermined number (for example, three in FIG. 4) of accommodation sections 72d from a tip end side of carrier tape 72 are empty accommodation sections 72d1 in which component 91 is not accommodated. Multiple accommodation sections 72d are provided at predetermined pitch intervals in a longitudinal direction of carrier tape 72 at the center portion in a width direction of base tape 72a.

Each of multiple feed holes 72e is a through hole, and is used when carrier tape 72 is conveyed in the conveyance direction (the second end side (arrow Y2 direction) in the second direction). Multiple feed holes 72e are provided at a predetermined pitch interval in the longitudinal direction of carrier tape 72 on the first end side in the width direction of base tape 72a. Cover tape 72b closes accommodation sections 72d of base tape 72a. Cover tape 72b is attached to the upper surfaces of both end portions of base tape 72a in the width direction by, for example, adhesive 72f or thermocompression bonding. Bottom tape 72c is attached to the lower surface of base tape 72a by, for example, adhesive 72f or thermocompression bonding, and prevents component 91 accommodated in accommodation section 72d from falling off.

A central portion of side plate 62 on a first end side (arrow X1 direction) in the first direction of feeder 60 is open in order to facilitate attachment and detachment of reel 70. At least one of the material of carrier tape 72, the width dimension of carrier tape 72, the width dimension of reel 70, and the diameter dimension of reel 70 is different among multiple types of reels 70, and there are multiple types of feeders 60 corresponding to multiple types of reels 70. Feeder 60 includes collection position 63, sprocket 64, and a tape peeling section.

Collection position 63 is provided on a second end side (arrow Y2 direction) in the second direction of the upper surface of feeder 60, and the component mounter collects component 91 at collection position 63. Sprocket 64 is rotatably provided on a first end side (arrow Y1 direction) in the second direction with respect to collection position 63. A teeth portion of sprocket 64 engage with feed holes 72e of carrier tape 72. Sprocket 64 is intermittently driven by a drive motor and conveys carrier tape 72 at a constant pitch. The tape peeling section can peel off cover tape 72b from base tape 72a immediately before collection position 63 to take out component 91. After passing through collection position 63, carrier tape 72 is cut by a tape cutting device provided in the component mounter.

An identification code for identifying feeder 60 is given to each of feeders 60. Feeder 60 is provided with a feeder control section. The feeder control section stores the identification information of feeder 60 and the identification information of reel 70, and controls the component supply operation. When feeder 60 is held by feeder holding section 21, the connectors are fitted to each other, and the feeder control section is communicably connected to setup device 10a.

Reel attachment mechanism 22 is provided on a first end side (arrow X1 direction) in the first direction of feeder holding section 21. Reel attachment mechanism 22 uses reel transfer mechanism 40 to change reel 70 from a horizontal posture to a vertical posture and attach reel 70 to feeder 60 at the work execution position. Reel attachment mechanism 22 includes pair of guide rails 22a and 22a, moving table 22b, attachment material 22c, placement area 22d, and temporary placement area 22e. In reel attachment mechanism 22, a mechanism that changes reel 70 in the horizontal posture to the vertical posture and a mechanism that attaches reel 70 in the vertical posture to feeder 60 may be separated.

Pair of guide rails 22a and 22a extends along the first direction (arrow X direction) at a substantially central position in the second direction (arrow Y direction) of first housing 11, and is disposed in parallel to be separated from each other. Moving table 22b extends along the second direction (arrow Y direction), and is provided to straddle the upper side of pair of guide rails 22a and 22a. As illustrated in FIGS. 1 and 2, moving table 22b moves along pair of guide rails 22a and 22a, and reciprocates between a standby position provided on the first end side (arrow X1 direction) in the first direction and feeder holding section 21 provided on the second end side (arrow X2 direction) in the first direction.

Attachment material 22c is formed in a square bar shape, and is provided to extend upward from moving table 22b. Attachment material 22c faces reel holding shaft 61 of feeder 60 at the work execution position. Specifically, attachment material 22c is provided at a position separated by a predetermined distance from a tip end portion of reel holding shaft 61 toward the first end side (arrow X1 direction) in the first direction. Attachment material 22c swings (arrow SW1 in FIG. 1) between an upright posture illustrated in FIGS. 1 and 2 and a horizontal posture in which attachment material 22c is tilted toward the second end side (arrow X2 direction) in the first direction around swing shaft 22cl provided on moving table 22b side. Collection section 22c2 is provided on an end portion different from an end portion of swing shaft 22cl side of attachment material 22c. Collection section 22c2 detachably collects reel 70. As collection section 22c2, a claw portion inserted into the center hole of reel 70, a gripping mechanism that grips a peripheral edge of reel 70, a pickup mechanism that picks up reel 70 using negative pressure, or the like can be used.

Placement area 22d is provided on the first end side (arrow X1 direction) in the first direction in pair of guide rails 22a and 22a. In placement area 22d, reel 70 to be attached is placed in a horizontal posture. Temporary placement area 22e is provided on pair of guide rails 22a and 22a on the second end side (arrow X2 direction) in the first direction with respect to placement area 22d. In temporary placement area 22e, when reel attachment mechanism 22 changes the use order of reels 70, reels 70 are temporarily placed in the horizontal posture and the use order of reels 70 is changed. In temporary placement area 22e, an area in which multiple reels 70 can be temporarily placed is secured. Moving table 22b and attachment material 22c move above placement area 22d and temporary placement area 22e.

As illustrated in FIG. 2, tape loading mechanism 23 is provided near feeder holding section 21. Tape loading mechanism 23 loads carrier tape 72 in feeder 60 so that carrier tape 72 can be fed. For example, an articulated robot can be used as tape loading mechanism 23. Tape loading mechanism 23 of the embodiment includes articulated arm 23a, camera 23b, and multiple fingers 23c.

Articulated arm 23a can perform operations such as rotation and bending of the arm, and can adjust the positions and directions of camera 23b and multiple fingers 23c. Camera 23b is provided at a tip end portion of articulated arm 23a. Camera 23b images feeder 60 at the work execution position to detect the positions and the states of reel 70 and carrier tape 72. Multiple fingers 23c are provided side by side with camera 23b at the tip end portion of articulated arm 23a. Multiple fingers 23c can perform a moving operation, a twisting operation, and the like in addition to the operation of gripping and releasing a work target.

Multiple fingers 23c loads carrier tape 72 so that feed hole 72e at a tip end portion of carrier tape 72 engages with sprocket 64, and sets carrier tape 72 in a feedable state. Multiple fingers 23c facilitate the loading operation of carrier tape 72 by rotating reel 70 around reel holding shaft 61 as necessary. Tape loading mechanism 23 takes a retracted posture in which articulated arm 23a is bent not to hinder the attaching and detaching operation of reel 70 in a time period other than the operation time.

Reel detachment mechanism 24 is provided on the first end side (arrow X1 direction) in the first direction of feeder holding section 21, and is disposed above reel attachment mechanism 22. Reel detachment mechanism 24 detaches reel 70 from feeder 60 at the work execution position. Reel detachment mechanism 24 includes guide rail 24a, moving table 24b, detachment material 24c, and retrieval box 24d.

Guide rail 24a is provided in the vicinity of the ceiling of first housing 11, and is formed to extend along the second direction (arrow Y direction). Moving table 24b is formed to extend along the first direction (arrow X direction), and is provided below guide rail 24a. As illustrated in FIGS. 1 and 2, moving table 24b moves along guide rail 24a and reciprocates between feeder holding section 21 and a standby position provided on the second end side (arrow Y2 direction) in the second direction.

Detachment material 24c is formed of a thick plate-shaped member longer than moving table 24b, and is provided to extend along the first direction (arrow X direction) below moving table 24b. Detachment material 24c swings (arrow SW2 in FIG. 1) between a horizontal posture illustrated in FIGS. 1 and 2 and a vertical posture in which detachment material 24c is tilted downward around swing shaft 24cl provided on the second end side (arrow X2 direction) in the first direction of moving table 24b. Collection section 24c2 is provided on an end portion on a side different from the end portion on swing shaft 24cl side of detachment material 24c. Collection section 24c2 detachably collects reel 70. The method of collecting collection section 24c2 may be the same as or different from collection section 22c2 of reel attachment mechanism 22.

Retrieval box 24d is provided to be positioned below detachment material 24c when moving table 24b is moved to the standby position. Retrieval box 24d retrieves multiple detached reels 70. Retrieval box 24d is formed in a box shape opening upward. Accordingly, retrieval box 24d can retrieve reel 70 that falls when collection section 24c2 of detachment material 24c releases reel 70.

Reel supply section 30 includes reel holding section 31 that is detachably provided. Pair of guide plates 12a and 12a extending along the second direction (arrow Y direction) is provided on the first end side (arrow X1 direction) in the first direction and the second end side (arrow X2 direction) in the first direction of the upper surface of base 12. Reel holding section 31 is placed between pair of guide plates 12a and 12a of base 12. As illustrated in FIG. 2, surfaces of pair of guide plates 12a and 12a facing each other on the first end side (arrow Y1 direction) in the second direction are formed in a tapered shape, and a separation distance on the first end side (arrow Y1 direction) in the second direction is longer than that on the second end side (arrow Y2 direction) in the second direction. This facilitates the work of inserting reel holding section 31 toward base 12 from the first end side (arrow Y1 direction) in the second direction.

Reel holding section 31 stacks and holds multiple reels 70 in a horizontal posture. Reel 70 is not limited to an unused reel, and may be a reel in use in which components 91 accommodated in carrier tape 72 has been collected halfway. Reel holding section 31 includes a circular plate-shaped holding plate 31 a provided horizontally, and round rod-shaped holding shaft 31b provided upward from the center of holding plate 31a and penetrating through the center hole of reel 70. Accordingly, reel holding section 31 can hold multiple reels 70 in a state where holding shaft 31b penetrates through the center holes of multiple reels 70 even when reels 70 differing in at least one of diameter dimension and width dimension coexist, and reel 70 can be easily taken out. Identification code 31c is given to an upper surface of holding plate 31a. Identification code 31c includes information for specifying reel holding section 31.

For example, the worker procures multiple reels 70 based on work instruction data, and performs a stacking work of stacking multiple reels 70 on reel holding section 31. The work instruction data indicates a work content of the setup work performed by setup device 10a. That is, in the work instruction data, the type information of multiple reels 70 required with the progress of the production of board products by the component mounter is associated with the type information of multiple feeders 60 applicable to reels 70. A known automated guided vehicle or the like can also be used to convey multiple reels 70.

Reel transfer mechanism 40 is provided on plate seat 12b extending from a bottom portion of base 12 to a second end side (arrow X2 direction) in the first direction. Reel transfer mechanism 40 includes support column 41, arm 42, and collection section 43. Support column 41 stands upward in the vertical direction on the second end side (arrow Y2 direction) in the second direction of plate seat 12b. Arm 42 is provided to be liftable and lowerable with respect to support column 41. Further, arm 42 is provided to be rotatable on a horizontal plane around rotation axis 44 close to support column 41.

Collection section 43 is provided to be extendable and contractible with respect to arm 42. Collection section 43 detachably collects reel 70. The collecting method of collection section 43 may be the same as or different from collection section 22c2 of reel attachment mechanism 22 and collection section 24c2 of reel detachment mechanism 24. Collection section 43 is provided with a code reader. The code reader reads identification code 31c of reel holding section 31. Further, the code reader can read the identification code of uppermost reel 70.

Reel transfer mechanism 40 functions as a part of reel attachment mechanism 22. Specifically, reel transfer mechanism 40 takes out reel 70 from reel holding section 31 by driving arm 42 and collection section 43. Further, reel transfer mechanism 40 places taken out reel 70 in placement area 22d or temporary placement area 22e in the state of the horizontal posture by driving arm 42 and collection section 43. Reel transfer mechanism 40 subsequently uses multiple reels 70 stacked on reel holding section 31 from the uppermost portion.

Feeder supply section 50 includes feeder accommodation section 51 that is detachably provided and feeder conveyance section 52. As illustrated in FIG. 2, storage space 13a in the upper portion of second housing 13 is open on the first end side (arrow Y1 direction) in the second direction, and can store multiple (for example, two in FIG. 2) feeder accommodation sections 51 arranged along the first direction (arrow X direction). As illustrated in FIG. 1, multiple roller conveyors 13b extending along the first direction (arrow X direction) are provided on a bottom surface defining storage space 13a, so that a storage operation of feeder accommodation section 51 is facilitated.

Feeder accommodation section 51 is formed in a box shape whose first end side (arrow Y1 direction) in the second direction is opened. Multiple slots having the same shape as slot 21b of feeder holding section 21 are formed on the bottom surface of feeder accommodation section 51. Feeder accommodation section 51 can accommodate multiple feeders 60 in a vertical posture arranged along the first direction (arrow X direction). When multiple feeders 60 are accommodated in feeder accommodation section 51 and feeder accommodation section 51 is properly stored in storage space 13a, the connectors of feeder 60 and feeder accommodation section 51 are fitted to each other, and multiple feeder control sections are communicably connected to setup device 10a.

An identification code for identifying feeder accommodation section 51 is given to feeder accommodation section 51. For example, the worker procures multiple feeders 60 to be used based on the work instruction data, and performs the accommodation work of accommodating feeders 60 in feeder accommodation section 51. The number of feeder accommodation sections 51 that can be accommodated in storage space 13a may be one or three or more. A known automated guided vehicle or the like can also be used for conveying multiple feeders 60.

Guide rail 13c is provided in a lower portion on the first end side (arrow Y1 direction) in the second direction of storage space 13a of second housing 13. Guide rail 13c is provided in storage space 13a over substantially the entire first direction (arrow X direction), and is provided to extend to the first end side (arrow Y1 direction) in the second direction of feeder holding section 21. Guide rail 13c is provided with feeder conveyance section 52. Feeder conveyance section 52 moves along guide rail 13c and reciprocates between feeder accommodation section 51 and feeder holding section 21.

Feeder conveyance section 52 is formed in a box shape having an opening portion on the second end side (arrow Y2 direction) in the second direction. Feeder conveyance section 52 includes a built-in space that temporarily incorporates feeder 60, and a feeder operation mechanism that conveys feeder 60 into built-in space through the opening portion and conveys feeder 60 out of built-in space. Accordingly, feeder conveyance section 52 can convey feeder 60 out of feeder accommodation section 51 and feeder holding section 21, and can convey feeder 60 into feeder accommodation section 51 and feeder holding section 21. An openable and closable safety fence is provided on the first end side (arrow Y1 direction) in the second direction of reel supply section 30 and feeder supply section 50, and the approach of the worker to reel supply section 30 and feeder supply section 50 is suppressed.

### 1-2. Control Example of Setup Device 10a

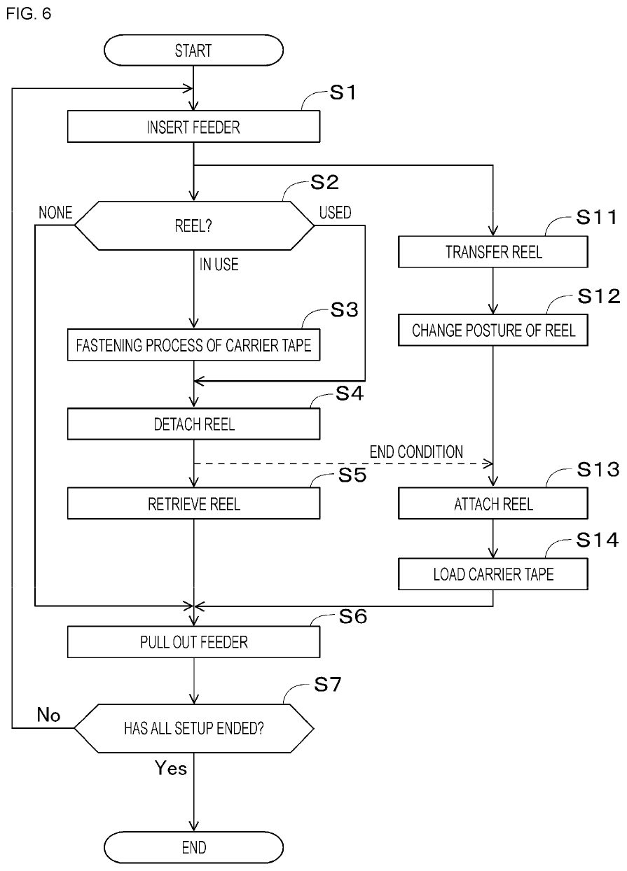

Setup device 10a causes feeder conveyance section 52 to convey feeder 60 corresponding to uppermost reel 70 of reel holding section 31 (step S1 illustrated in FIG. 6). Feeder conveyance section 52 pulls out and incorporates feeder 60 from feeder accommodation section 51, moves to feeder holding section 21, and inserts incorporated feeder 60 into feeder holding section 21. Accordingly, feeder 60 is held at the work execution position, and the identification code of feeder 60 is read.

When there is no feeder 60 applicable to uppermost reel 70 of reel holding section 31, reel 70 is placed in temporary placement area 22e by reel transfer mechanism 40. The above-described placement is repeated until applicable feeder 60 is present, and feeder 60 corresponding to uppermost reel 70 of reel holding section 31 is inserted into feeder holding section 21. After the control illustrated in step S1, in setup device 10a, a first-series control illustrated in steps S2 to S5 and a second-series control illustrated in steps S11 to S14 are executed in parallel.

In the first-series control, setup device 10a confirms the state of reel 70 based on the read identification code of feeder 60 or the read identification code of reel 70, and changes the control according to the state of reel 70 (step S2). Specifically, when feeder 60 is used in the component mounter in advance, there is a possibility that reel 70 in use in which components 91 accommodated in carrier tape 72 has been collected halfway is provided in feeder 60. In this case, tape loading mechanism 23 performs a fastening process of fixing the tip end portion of carrier tape 72 with a tape or the like to suppress slack of carrier tape 72 (step S3). In this case, tape loading mechanism 23 can wind carrier tape 72 around reel 70 as necessary. Thereafter, tape loading mechanism 23 takes a retracted posture in which articulated arm 23a is bent.

Next, reel detachment mechanism 24 detaches reel 70 from feeder 60 (step S4). Specifically, moving table 24b moves from the standby position to feeder holding section 21. Then, when detachment material 24c is swung from the horizontal posture to the vertical posture, collection section 24c2 abuts on reel 70 and collects reel 70. Then, when detachment material 24c returns from the vertical posture to the horizontal posture, collection section 24c2 pulls out reel 70 from reel holding shaft 61 and holds reel 70 in the horizontal posture. In this case, setup device 10a deletes the identification information of reel 70 from the storage section of the feeder control section of feeder 60. Further, setup device 10a transmits the identification information of feeder 60 from which reel 70 has been detached to a higher-level management device. At this time, setup device 10a may transmit the identification information of detached reel 70 together with the identification information of feeder 60 to the higher-level management device.

Next, reel detachment mechanism 24 retrieves reel 70 (step S5). Specifically, first, moving table 24b moves from feeder holding section 21 to the standby position. Then, collection section 24c2 releases reel 70. Thus, released reel 70 falls into retrieval box 24d and is retrieved. When reel 70 is retrieved, the first-series control is in a standby state until the second-series control ends.

There is a possibility that feeder 60 is provided with used reel 70 from which all components 91 accommodated in carrier tape 72 have been collected (step S2). In this case, in the first-series control, the control illustrated in step S3 is omitted, and the controls illustrated in step S4 and step S5 are executed. There is a possibility that feeder 60 is not provided with reel 70 (step S2). In this case, in the first-series control, the control illustrated in steps S3 to S5 is omitted.

In the second-series control, reel transfer mechanism 40 collects uppermost reel 70 of reel holding section 31 using collection section 43, and places reel 70 in placement area 22d (step S11). Then, reel transfer mechanism 40 returns collection section 43 to above reel holding section 31. When there is no applicable feeder 60, reel transfer mechanism 40 places reel 70 in temporary placement area 22e.

Next, reel attachment mechanism 22 changes the posture of reel 70 in placement area 22d (step S12). Specifically, first, attachment material 22c is changed from the upright posture to the horizontal posture, and collection section 22c2 abuts on reel 70 to collect reel 70. Then, attachment material 22c is returned from the horizontal posture to the upright posture, and collection section 22c2 changes reel 70 from the horizontal posture to the vertical posture and holds reel 70. When reel 70 in temporary placement area 22e is used, moving table 22b moves to the second end side (arrow X2 direction) in the first direction by a predetermined distance before attachment material 22c shifts from the upright posture to the horizontal posture. The second-series control is in a standby state until an end condition indicating the completion of the control of step S4 of the first series is satisfied. This avoids interference between reel attachment mechanism 22 and reel detachment mechanism 24.

When the end condition described above is satisfied, reel attachment mechanism 22 attaches reel 70 on feeder 60 (step S13). Specifically, in a state where collection section 22c2 holds reel 70 in the vertical posture, moving table 22b moves to feeder holding section 21. Accordingly, reel 70 moves toward reel holding shaft 61 and is attached to reel holding shaft 61. The movement of moving table 22b can be performed simultaneously with the movement of moving table 24b to the standby position.

When the attachment of reel 70 ends, setup device 10a stores the identification information of reel 70 in the feeder control section of feeder 60 to which reel 70 is attached. Further, setup device 10a transmits the identification information of feeder 60 and the identification information of reel 70 provided on feeder 60 to the higher-level management device in association with each other. Moving table 22b returns to the standby position. Next, tape loading mechanism 23 loads carrier tape 72 until feed holes 72e of carrier tape 72 engage with the teeth portion of sprocket 64 (step S14).

When the first-series control and the second-series control end, feeder conveyance section 52 pulls out feeder 60 from feeder holding section 21, incorporates feeder 60 therein, moves feeder 60 to feeder accommodation section 51, and inserts incorporated feeder 60 into feeder accommodation section 51 (step S6). Thus, the setup work for one feeder 60 ends. Setup device 10a determines whether the setup work for all feeders 60 has ended (step S7). When the setup work for all feeders 60 has ended (Yes in step S7), the control by setup device 10a temporarily ends. When the setup work for all feeders 60 has not ended (No in step S7), the control by setup device 10a returns to the control illustrated in step S1, and the control described above is repeated until the setup work for all feeders 60 ends.

When the control by setup device 10a ends, for example, the worker conveys feeder accommodation section 51 accommodating feeder 60 that has been set up to the component mounter, and performs the setup change of feeder 60. When reel 70 is placed in temporary placement area 22e, when the worker accommodates feeder 60 applicable to reel 70 in feeder accommodation section 51, reel 70 becomes usable. Further, reel 70 left unused in temporary placement area 22e is returned to reel holding section 31 by reel transfer mechanism 40 and retrieved by the worker. Further, the above-described conveyance work by the worker can also be automated using a known automated guided vehicle or the like.

### 1-3. Configuration Example of Feeder Unit 10b

Multiple types of kitting devices 10 include feeder unit 10b. In feeder unit 10b, reel 70 is set on feeder 60 by a worker. As long as feeder unit 10b can hold feeder 60 on which reel 70 is set by the worker, feeder unit 10b may take various configurations.

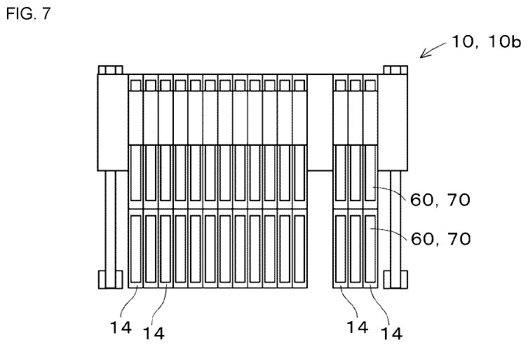

For example, feeder unit 10b illustrated in FIG. 7 includes multiple slots 14. Each of multiple slots 14 is formed similarly to slot 21b of feeder holding section 21 of setup device 10a, and can hold feeder 60 on which reel 70 is set by the worker. Feeder unit 10b is provided in the component supply device of component mounter 99, and can supply component 91 to component mounter 99.

### 1-4. Configuration Example of Kitting Device Extraction System 80

As described above, as kitting device 10, there are multiple types of kitting devices 10 that perform different setting work for setting reel 70 on feeder 60. Therefore, it is necessary to extract corresponding kitting device 10t capable of performing the setting work according to a state of reel 70. In the embodiment, kitting device extraction system 80 is provided. Kitting device extraction system 80 extracts corresponding kitting device 10t capable of performing setting work based on the state of reel 70.

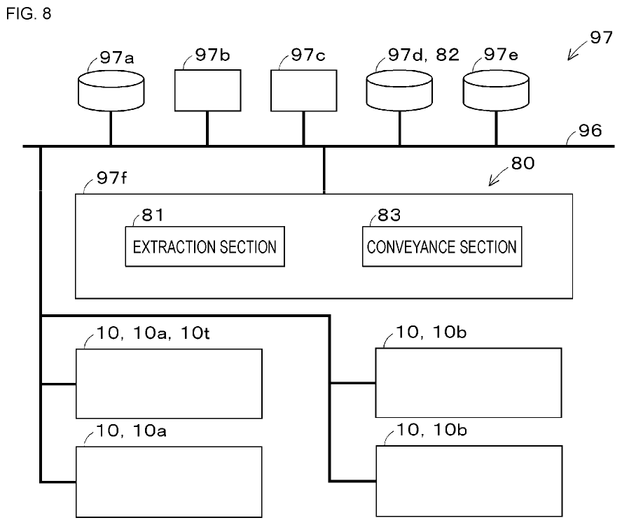

Kitting device extraction system 80 includes multiple types of kitting devices 10 and extraction section 81. Kitting device extraction system 80 may include storage section 82. Kitting device extraction system 80 may include conveyance section 83. In addition, as described above, as long as multiple types of kitting devices 10 can set reel 70 on feeder 60, kitting device 10 may take various configurations. As illustrated in FIG. 8, kitting device extraction system 80 of the embodiment includes multiple types (two types) of kitting devices 10 including setup device 10a and feeder unit 10b, extraction section 81, storage section 82, and conveyance section 83.

Extraction section 81 and conveyance section 83 can be provided in various control devices and management devices. For example, at least one of extraction section 81 and conveyance section 83 can be provided in a control device of kitting device 10, production management system 97f described later, a control device of storage 110 described later, or the like. At least one of extraction section 81 and conveyance section 83 may be formed on a cloud. Storage section 82 stores information described later. Storage section 82 may store information described later and may be any known storage device, database, or the like. Storage section 82 can also be formed on a cloud.

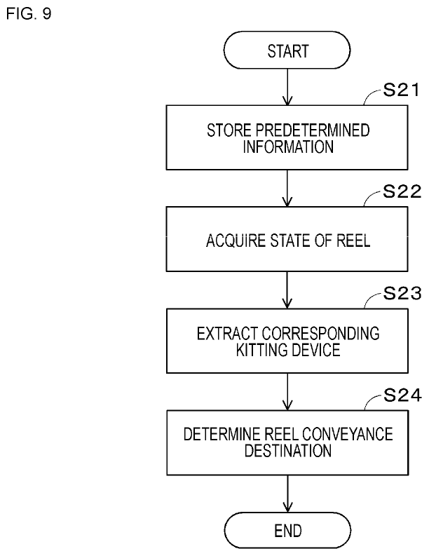

As illustrated in FIG. 8, extraction section 81 and conveyance section 83 of the embodiment are provided in production management system 97f. Storage section 82 of the embodiment is provided in material database 97d described later. Further, kitting device extraction system 80 of the embodiment executes control in accordance with a flowchart illustrated in FIG. 9. Extraction section 81 performs processing illustrated in steps S22 and S23. Storage section 82 performs the processing illustrated in step S21. Conveyance section 83 performs the processing illustrated in step S24.

### 1-4-1. Extraction Section 81 and Storage Section 82

Extraction section 81 extracts corresponding kitting device 10t capable of performing setting work based on a state of reel 70 from multiple types of kitting devices 10 (step S22 and step S23 illustrated in FIG. 9). As long as extraction section 81 can extract corresponding kitting device 10t based on the state of reel 70, extraction section 81 may take various configurations.

For example, corresponding kitting device 10t may be different depending on whether reel 70 is unused or in use. Specifically, carrier tape 72 is wound around main body portion 71 of reel 70. For example, when reel 70 is repeatedly attached to and detached from feeder 60, main body portion 71 of reel 70 may be damaged. Reel 70 having main body portion 71 damaged may be difficult to perform the setting work by setup device 10a. In this case, the setting work is performed by the worker in feeder unit 10b. That is, in the embodiment described above, corresponding kitting device 10t when reel 70 is unused is setup device 10a, and corresponding kitting device 10t when reel 70 is in use is feeder unit 10b.

Whether reel 70 is unused or in use is different for each reel 70, and can be known from a component remaining number that is a remaining number of components 91 accommodated in carrier tape 72 of reel 70. Then, kitting device extraction system 80 may include storage section 82. Storage section 82 stores the reel identification information for identifying reel 70 and the component remaining number that is a remaining number of components 91 accommodated in carrier tape 72 of reel 70 in association with each other (step S21 illustrated in FIG. 9).

As illustrated in FIG. 8, storage section 82 of the embodiment is provided in material database 97d of production system 97. FIG. 8 illustrates an example of production system 97 for producing a board product by a board work machine for performing predetermined board work on board 90. Production system 97 is communicably connected to various board work machines including component mounter 99 by a wired or wireless communication section 96. Production system 97 is communicably connected to kitting device 10 via communication section 96. Further, production system 97 is communicably connected to storage 110 via communication section 96.

Production system 97 of the embodiment includes maintenance database 97a, higher level system 97b, location management system 97c, material database 97d, layout management system 97e, and production management system 97f. Maintenance database 97a stores maintenance information (for example, maintenance timing, the number of times of maintenance execution, and the like) of various members to be used in production of board products. Maintenance database 97a stores, for example, maintenance information for feeder 60 and the like. Higher level system 97b is a higher-level management system and manages various types of information.

Location management system 97c manages location information of the members to be used on the production floor. Location management system 97c manages, for example, location information of feeder 60 and reel 70. Material database 97d stores information related to the members to be used. Material database 97d stores, for example, component information, manufacturers of feeder 60 and reel 70, and the like. The component information includes information on the component remaining number and information on the electrical characteristics of component 91. The component information is stored in association with the identification information of reel 70.

Layout management system 97e stores a configuration of a production line for producing board products, a configuration of a board work machine provided in each production line, and the like. Production management system 97f manages production of board products in the board work machine. In addition, production management system 97f stores information related to the members to be used. Production management system 97f stores, for example, a mounting position of feeder 60 in the component supply device of component mounter 99, and the like. Production management system 97f stores, for example, component information. The component information includes information about the shape of component 91.

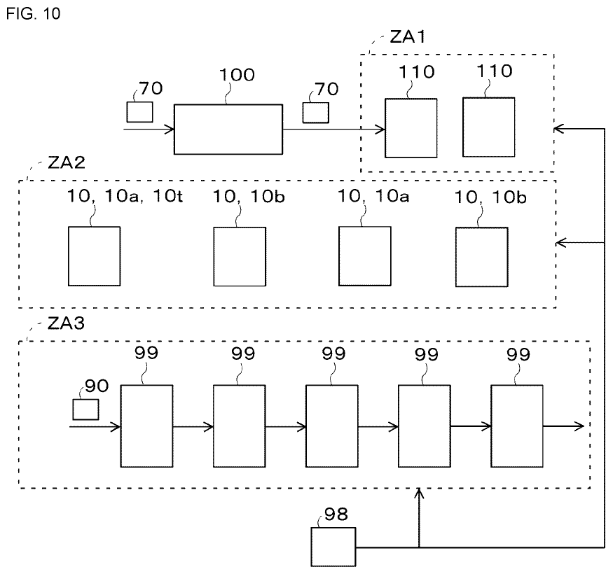

In addition, as illustrated in FIG. 10, the production facility of the embodiment includes arrival section 100, storage 110, kitting device 10, and component mounter 99. Reel 70 is delivered to arrival section 100, and for example, an identification code is attached to reel 70 by the worker. In addition, storage section 82 sets and stores the component remaining number on reel 70 to an initial value (the component remaining number when reel 70 is unused). Thereafter, reel 70 is stored in storage 110 and retrieved when it is required for component mounter 99. Storage 110 is provided in storage area ZA1. As long as storage 110 can store reel 70, storage 110 may take various configurations. Storage 110 of the embodiment is an automated storage in which retrieval of reel 70 is automated.

As described above, in kitting device 10, reel 70 is set on feeder 60. Kitting device 10 is provided in off-line setup area ZA2. The production facility of the embodiment includes both setup device 10a and feeder unit 10b. Feeder 60, on which reel 70 is set, is conveyed to component mounter 99 that mounts components 91 on board 90. Component mounter 99 is provided in production area ZA3. Reel 70 used in component mounter 99 is detached from feeder 60 in kitting device 10 and stored in storage 110. In addition, storage section 82 stores the component remaining number by subtracting the component number on reel 70 used in component mounter 99 from the component remaining number on reel 70. The conveyance of feeder 60 and reel 70 may be performed by the worker or by automated guided vehicle 98.

When corresponding kitting device 10t is different depending on whether reel 70 is unused or in use, extraction section 81 determines whether reel 70 is unused or in use based on the reel identification information and the component remaining number stored in storage section 82, and acquires the state of reel 70. As described above, reel 70 is provided with an identification code. Extraction section 81 acquires, from storage section 82, the component remaining number stored in association with the identification information of reel 70 read from the identification code provided on reel 70.

When the acquired component remaining number matches the initial value (the component remaining number when reel 70 is unused), extraction section 81 determines that reel 70 is unused. In this case, in the example described above, since setup device 10a is corresponding kitting device 10t, extraction section 81 extracts setup device 10a, which is corresponding kitting device 10t. When feeder unit 10b is corresponding kitting device 10t, extraction section 81 extracts feeder unit 10b, which is corresponding kitting device 10t.

When the acquired component remaining number does not match the initial value (smaller than the initial value), extraction section 81 determines that reel 70 is in use. In this case, in the example described above, since feeder unit 10b is corresponding kitting device 10t, extraction section 81 extracts feeder unit 10b, which is corresponding kitting device 10t. When setup device 10a is corresponding kitting device 10t, extraction section 81 extracts setup device 10a, which is corresponding kitting device 10t. The reading work of the identification code can be performed by a code reader provided in setup device 10a, storage 110, or the like. The reading work of the identification code can also be performed by the worker using a code reader or the like.

Storage section 82 can also store reel identification information for identifying reel 70 in association with use state information indicating whether reel 70 is unused or in use. When reel 70 is used in component mounter 99, reel 70 changes from unused to in use. Here, storage section 82 stores use state information indicating that reel 70 is unused before reel 70 is used in component mounter 99. Storage section 82 stores use state information indicating that reel 70 is in use after reel 70 is used in component mounter 99.

In the embodiment described above, when corresponding kitting device 10t is different depending on whether reel 70 is unused or in use, extraction section 81 can acquire the state of reel 70 based on the reel identification information and the use state information stored in storage section 82. Similarly to the case of the component remaining number, extraction section 81 acquires, from storage section 82, the use state information stored in association with the identification information of reel 70 read from the identification code provided on reel 70.

In the example described above, when the acquired use state information is the use state information indicating that reel 70 is unused, extraction section 81 extracts setup device 10a, which is corresponding kitting device 10t. When feeder unit 10b is corresponding kitting device 10t, extraction section 81 extracts feeder unit 10b, which is corresponding kitting device 10t. In addition, when the acquired use state information is the use state information indicating that reel 70 is in use, extraction section 81 extracts feeder unit 10b, which is corresponding kitting device 10t. When setup device 10a is corresponding kitting device 10t, extraction section 81 extracts setup device 10a, which is corresponding kitting device 10t.

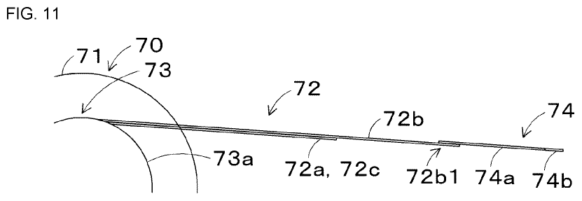

Corresponding kitting device 10t may be different depending on the fixing method of tip end portion 72bl of cover tape 72b. Specifically, as illustrated in FIGS. 4 and 5, in carrier tape 72, cover tape 72b that closes accommodation section 72d is attached to base tape 72a provided with accommodation section 72d that accommodates component 91. As illustrated in FIG. 3, carrier tape 72 is spirally wound around reel 70. As illustrated in FIG. 11, for example, the tip end side of carrier tape 72 of unused reel 70 is formed such that cover tape 72b protrudes more than base tape 72a. Tip end portion 72b1 of cover tape 72b and outer peripheral portion 73a of spiral tape 73 are fixed by first fixing tape 74.

FIG. 11 is a schematic view of reel 70 as viewed in the rotation axis direction, and shows a state, in which first fixing tape 74 is peeled off from outer peripheral portion 73a of spiral tape 73 and the tip end side of carrier tape 72 is extended, for convenience of description. When an adhesive is provided over the entire surface of first fixing tape 74 on the side fixed to outer peripheral portion 73a of spiral tape 73, it is difficult to peel off first fixing tape 74. Therefore, as illustrated in FIG. 11, first fixing tape 74 includes adhesive portion 74a and non-adhesive portion 74b.

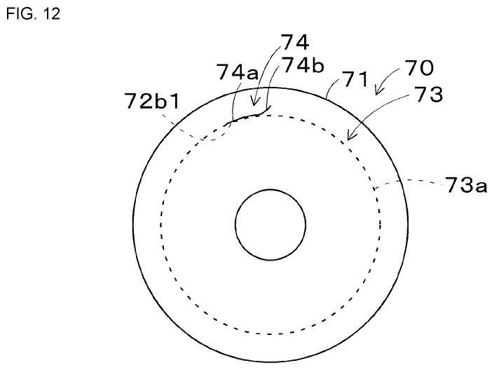

Adhesive portion 74a is a portion where an adhesive is provided. The adhesive is provided on a portion on the base end side of first fixing tape 74 on the surface of first fixing tape 74 on the side fixed to outer peripheral portion 73a of spiral tape 73. Non-adhesive portion 74b is a portion on the tip end side of first fixing tape 74, and is a portion where the adhesive for fixing first fixing tape 74 and outer peripheral portion 73a of spiral tape 73 is not provided. FIG. 12 is a transparent view of reel 70 to which carrier tape 72 is fixed by first fixing tape 74. As described above, in the present description, a fixing method in which outer peripheral portion 73a of spiral tape 73 around which carrier tape 72 is spirally wound and tip end portion 72b1 of cover tape 72b are fixed by first fixing tape 74 is referred to as a first fixing method.

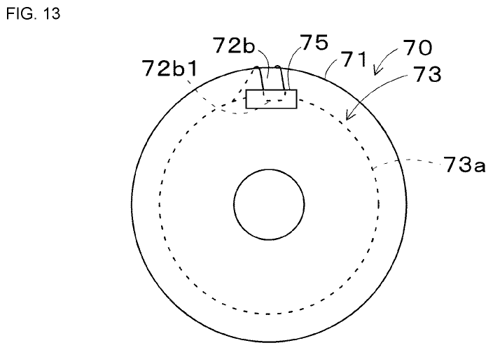

As illustrated in FIG. 13, for example, tip end portion 72b1 of cover tape 72b of reel 70 in use can be fixed to the side surface of main body portion 71 of reel 70 by second fixing tape 75. FIG. 13 is a transparent view of reel 70 to which carrier tape 72 is fixed by second fixing tape 75. As described above, in the present description, a fixing method in which the side surface of main body portion 71 of reel 70 and tip end portion 72b1 of cover tape 72b are fixed by second fixing tape 75 is referred to as a second fixing method.

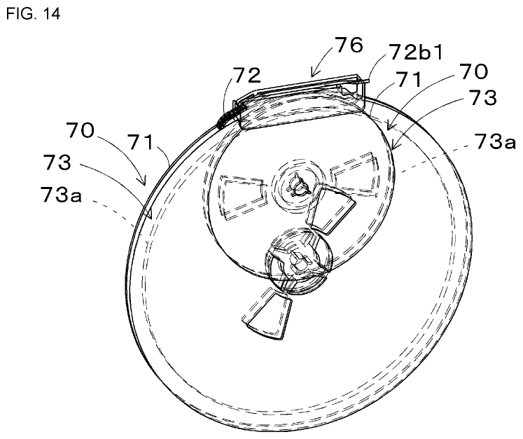

As illustrated in FIG. 14, for example, tip end portion 72b1 of cover tape 72b of reel 70 in use can be fixed to fixing device 76. FIG. 14 is a transparent view of reel 70 to which carrier tape 72 is fixed by fixing device 76. As illustrated in FIG. 14, fixing device 76 is detachably attached to the outer peripheral portion of main body portion 71 of reel 70, and tip end portion 72b1 of cover tape 72b is fixed thereto. Fixing device 76 can be attached to multiple types of reels 70 having different diameter dimensions. In FIG. 14, for convenience of description, two reels 70 having different diameter dimensions are illustrated. As described above, the fixing method of tip end portion 72b1 of cover tape 72b includes a fixing method other than the first fixing method and the second fixing method.

For example, reel 70 can fix tip end portion 72b1 of cover tape 72b by multiple fixing methods including the first fixing method and the second fixing method. In this case, storage section 82 can store reel identification information for identifying reel 70 in association with fixing method information indicating a fixing method of tip end portion 72b1 of cover tape 72b. For example, in the case of reel 70 to which tip end portion 72b1 of cover tape 72b is fixed by the first fixing method, storage section 82 stores reel identification information for identifying reel 70 and fixing method information indicating the first fixing method in association with each other.

As described above, for example, the fixing method of tip end portion 72b1 of cover tape 72b is different depending on whether reel 70 is unused or in use. Therefore, storage section 82 can acquire the fixing method of tip end portion 72b1 of cover tape 72b based on whether reel 70 is unused or in use, and can store the fixing method information. In addition, kitting device extraction system 80 can also image reel 70 using an imaging device and perform image processing on an image in which tip end portion 72b1 of cover tape 72b is imaged. In this case, storage section 82 can store the fixing method information based on the fixing method of tip end portion 72b1 of cover tape 72b recognized by the image processing.

When the fixing method of tip end portion 72b1 of cover tape 72b is the first fixing method, it is necessary to peel off first fixing tape 74 in order to perform the setting work in kitting device 10. In this case, kitting device 10 capable of peeling off first fixing tape 74 is corresponding kitting device 10t. Similarly, when the fixing method of tip end portion 72b1 of cover tape 72b is the second fixing method, it is necessary to peel off second fixing tape 75 in order to perform the setting work in kitting device 10. In this case, kitting device 10 capable of peeling off second fixing tape 75 is corresponding kitting device 10t. When tip end portion 72b1 of cover tape 72b is fixed by fixing device 76, it is necessary to detach fixing device 76 from reel 70 in order to perform the setting work in kitting device 10. In this case, kitting device 10 capable of detaching fixing device 76 is corresponding kitting device 10t.

In the embodiment described above, when corresponding kitting device 10t is different depending on the difference in the fixing methods of tip end portion 72b1 of cover tape 72b, extraction section 81 can acquire the state of reel 70 based on the reel identification information and the fixing method information stored in storage section 82. Similarly to the case of the component remaining number and the use state information, extraction section 81 acquires, from storage section 82, the fixing method information stored in association with the identification information of reel 70 read from the identification code provided on reel 70.

When the acquired fixing method information is fixing method information indicating the first fixing method, extraction section 81 recognizes reel 70 to which tip end portion 72b1 of cover tape 72b is fixed by first fixing method. In this case, extraction section 81 extracts kitting device 10 capable of peeling off first fixing tape 74, which is corresponding kitting device 10t. Specifically, when kitting device 10 capable of peeling off first fixing tape 74 is setup device 10a, extraction section 81 extracts setup device 10a, which is corresponding kitting device 10t. In this case, first fixing tape 74 is peeled off by setup device 10a. When kitting device 10 capable of peeling off first fixing tape 74 is feeder unit 10b, extraction section 81 extracts feeder unit 10b, which is corresponding kitting device 10t. In this case, first fixing tape 74 is peeled off by the worker.

Similarly, when the acquired fixing method information is fixing method information indicating the second fixing method, extraction section 81 recognizes reel 70 to which tip end portion 72b1 of cover tape 72b is fixed by second fixing method. In this case, extraction section 81 extracts kitting device 10 capable of peeling off second fixing tape 75, which is corresponding kitting device 10t. Specifically, when kitting device 10 capable of peeling off second fixing tape 75 is setup device 10a, extraction section 81 extracts setup device 10a, which is corresponding kitting device 10t. In this case, second fixing tape 75 is peeled off by setup device 10a. When kitting device 10 capable of peeling off second fixing tape 75 is feeder unit 10b, extraction section 81 extracts feeder unit 10b, which is corresponding kitting device 10t. In this case, second fixing tape 75 is peeled off by the worker.

When the acquired fixing method information is fixing method information indicating fixation by fixing device 76, extraction section 81 recognizes reel 70 to which tip end portion 72b1 of cover tape 72b is fixed by fixing device 76. In this case, extraction section 81 extracts kitting device 10 capable of detaching fixing device 76, which is corresponding kitting device 10t. Specifically, when kitting device 10 capable of detaching fixing device 76 is setup device 10a, extraction section 81 extracts setup device 10a, which is corresponding kitting device 10t. In this case, fixing device 76 is detached by setup device 10a. When kitting device 10 capable of detaching fixing device 76 is feeder unit 10b, extraction section 81 extracts feeder unit 10b, which is corresponding kitting device 10t. In this case, fixing device 76 is detached by the worker.

Further, it is assumed that it is defined that tip end portion 72b1 of cover tape 72b is fixed by the first fixing method when reel 70 is unused, and tip end portion 72b1 of cover tape 72b is fixed by the second fixing method when reel 70 is in use. That is, it is assumed that corresponding kitting device 10t is different depending on both whether reel 70 is unused or in use, and the difference in fixing methods of tip end portion 72b1 of cover tape 72b. In this case, storage section 82 may store the reel identification information for identifying reel 70 and the component remaining number that is a remaining number of components 91 accommodated in carrier tape 72 of reel 70 in association with each other. Storage section 82 may store reel identification information for identifying reel 70 in association with use state information indicating whether reel 70 is unused or in use.

In the above-described case, extraction section 81 can determine the fixing method of tip end portion 72b1 of cover tape 72b based on the reel identification information and the component remaining number stored in storage section 82, and acquire the state of reel 70. In addition, in the above-described case, extraction section 81 can also determine the fixing method of tip end portion 72b1 of cover tape 72b based on the reel identification information and the use state information stored in storage section 82, and acquire the state of reel 70. In either case, extraction section 81 can extract corresponding kitting device 10t, similar to the case described above for the fixing method information. The above-described can be applied similarly in cases where it is defined that tip end portion 72b1 of cover tape 72b is fixed by the first fixing method when reel 70 is in use and tip end portion 72b1 of cover tape 72b is fixed by the second fixing method when reel 70 is unused.

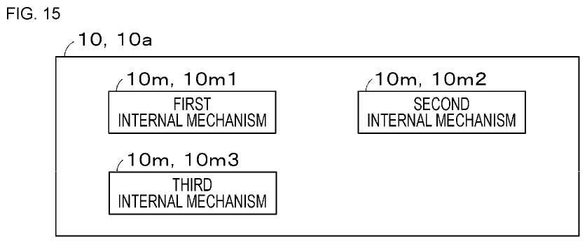

Furthermore, in any configuration described in the present description, multiple types of kitting devices 10 include setup device 10a that automatically sets reel 70 on feeder 60 so that components 91 can be supplied from feeder 60. As illustrated in FIG. 15, multiple types of kitting devices 10 include setup device 10a including multiple types of internal mechanisms 10m usable for the setting work. The forms and the number of types of internal mechanisms 10m are not limited. Setup device 10a illustrated in FIG. 15 includes multiple types (three types) of internal mechanisms 10m including first internal mechanism 10m1, second internal mechanism 10m2, and third internal mechanism 10m3. For example, first internal mechanism 10m1 is a peeling mechanism capable of peeling first fixing tape 74. Second internal mechanism 10m2 is a peeling mechanism capable of peeling second fixing tape 75. Third internal mechanism 10m3 is a detachable mechanism capable of detaching fixing device 76 from reel 70.

In the embodiment described above, extraction section 81 can also extract setup device 10a in which internal mechanism 10m is selected so that setup device 10a becomes corresponding kitting device 10t. For example, when extraction section 81 recognizes reel 70 to which tip end portion 72b1 of cover tape 72b is fixed by the first fixing method, extraction section 81 extracts setup device 10a in which first internal mechanism 10m1 is selected. Similarly, when extraction section 81 recognizes reel 70 to which tip end portion 72b1 of cover tape 72b is fixed by the second fixing method, extraction section 81 extracts setup device 10a in which second internal mechanism 10m2 is selected.

When extraction section 81 recognizes reel 70 to which tip end portion 72b1 of cover tape 72b is fixed by fixing device 76, extraction section 81 extracts setup device 10a in which third internal mechanism 10m3 is selected. Extracting setup device 10a in which internal mechanism 10m is selected can be applied in any of the configurations described above for extracting setup device 10a. In the configuration of extracting setup device 10a in which internal mechanism 10m is selected, extraction section 81 may also be provided in the control device of setup device 10a. Furthermore, in any configuration described in the present description, multiple types of kitting devices 10 include feeder unit 10b in which reel 70 is set on feeder 60 by the worker.

### 1-4-2. Conveyance Section 83

As illustrated in FIG. 10, the production facility includes storage 110 for storing reel 70. In this configuration, kitting device extraction system 80 can include storage 110 and conveyance section 83. Conveyance section 83 determines the conveyance destination of reel 70 and conveys reel 70 (step S24 illustrated in FIG. 9).

Specifically, conveyance section 83 conveys reel 70 stored in storage 110 toward corresponding kitting device 10t. For example, it is assumed that setup device 10a, which is corresponding kitting device 10t, is extracted for predetermined reel 70 by extraction section 81. In this case, conveyance section 83 conveys reel 70 stored in storage 110 toward setup device 10a. Similarly, it is assumed that feeder unit 10b, which is corresponding kitting device 10t, is extracted for predetermined reel 70 by extraction section 81. In this case, conveyance section 83 conveys reel 70 stored in storage 110 toward feeder unit 10b.

In either case, reel 70 can be conveyed by the worker or by automated guided vehicle 98. Extraction section 81 can extract multiple corresponding kitting devices 10t. In this case, conveyance section 83 may convey reel 70 stored in storage 110 toward any corresponding kitting device 10t. Further, in a configuration in which storage 110 and conveyance section 83 are provided, extraction section 81 and conveyance section 83 may be provided in the control device of storage 110. The configuration including storage 110 and conveyance section 83 can be applied to any configuration described in the present description.

### 2. Example of Effect of Embodiment

With kitting device extraction system 80, it is possible to extract corresponding kitting device 10t capable of performing setting work based on a state of reel 70.

### REFERENCE SIGNS LIST

10: kitting device, 10a: setup device, 10m: internal mechanism, 10b: feeder unit, 10t: corresponding kitting device, 60: feeder, 70: reel, 71: main body portion, 72: carrier tape, 72a: base tape, 72b: cover tape, 72b1: tip end portion, 72d: accommodation section, 73: spiral tape, 73a: outer peripheral portion, 74: first fixing tape, 75: second fixing tape, 80: kitting device extraction system, 81: extraction section, 82: storage section, 83: conveyance section, 91: component, 110: storage

1. A kitting device extraction system comprising:
multiple types of kitting devices configured to perform different setting work for setting a reel, on which a carrier tape for accommodating components is wound, on a feeder; and
an extraction section configured to extract a corresponding kitting device capable of performing the setting work based on a state of the reel from the multiple types of kitting devices.

2. The kitting device extraction system according to claim 1, further comprising:
a storage section configured to store reel identification information for identifying the reel and a component remaining number that is a remaining number of the components accommodated in the carrier tape of the reel in association with each other,
wherein when the corresponding kitting device is different depending on whether the reel is unused or in use, the extraction section determines whether the reel is unused or in use based on the reel identification information and the component remaining number stored in the storage section, and acquires the state of the reel.

3. The kitting device extraction system according to claim 1, further comprising:
a storage section configured to store reel identification information for identifying the reel and use state information indicating whether the reel is unused or in use in association with each other,
wherein when the corresponding kitting device is different depending on whether the reel is unused or in use, the extraction section acquires the state of the reel based on the reel identification information and the use state information stored in the storage section.

4. The kitting device extraction system according to claim 1,
wherein the reel is capable of fixing a tip end portion of a cover tape that closes an accommodation section that accommodates the component to a base tape provided with the accommodation section by multiple fixing methods including a first fixing method in which an outer peripheral portion of a spiral tape on which the carrier tape, to which the cover tape is attached, is spirally wound and the tip end portion of the cover tape are fixed by a first fixing tape, and a second fixing method in which a side surface of a main body portion of the reel and the tip end portion of the cover tape are fixed by a second fixing tape,
the kitting device extraction system includes a storage section configured to store reel identification information for identifying the reel and fixing method information indicating the fixing method of the tip end portion of the cover tape in association with each other, and
the extraction section acquires the state of the reel based on the reel identification information and the fixing method information stored in the storage section when the corresponding kitting device is different depending on a difference in the fixing methods of the tip end portion of the cover tape.

5. The kitting device extraction system according to claim 1, wherein the multiple types of kitting devices include a setup device that automatically sets the reel on the feeder so that the components are capable of being supplied from the feeder.

6. The kitting device extraction system according to claim 5,
wherein the multiple types of kitting devices include the setup device including multiple types of internal mechanisms usable for the setting work, and
the extraction section extracts the setup device in which the internal mechanism is selected so that the setup device becomes the corresponding kitting device.

7. The kitting device extraction system according to claim 1, wherein the multiple types of kitting devices include a feeder unit in which the reel is set on the feeder by a worker.

8. The kitting device extraction system according to claim 1, further comprising:
a storage configured to store the reel; and
a conveyance section configured to convey the reel stored in the storage toward the corresponding kitting device.
